(19) United States
(12) Patent Application Publication
(10) Pub. No.: US 2015/0270144 A1
(43) Pub. Date: Sep. 24, 2015

(54) PATTERNED STRUCTURE OF SEMICONDUCTOR DEVICE AND METHOD FOR FABRICATING THE SAME

(71) Applicant: INOTERA MEMORIES, INC., Taoyuan County 333 (TW)

(72) Inventor: KUOYAO CHOU, TAICHUNG CITY (TW)

(73) Assignee: INOTERA MEMORIES, INC., Taoyuan County 333 (TW)

(21) Appl. No.: 14/220,278

(22) Filed: Mar. 20, 2014

(51) Int. Cl. H01L 21/3213; H01L 21/311; H01L 21/033; H01L 21/3105; H01L 23/532; H01L 21/02; H01L 21/32; H01L 21/265

(52) U.S. Cl. CPC H01L 21/32139; H01L 21/32; H01L 21/31144; H01L 21/2658; H01L 21/31058; H01L 21/31111; H01L 21/31122; H01L 23/53271; H01L 21/02532; H01L 21/02595; H01L 21/0332; H01L 21/0337; H01L 21/02112; H01L 21/02282; H01L 21/02592; H01L 21/32135

(57) ABSTRACT

The invention is directed to a method for fabricating a patterned structure of semiconductor device. First, a target layer and a hard mask layer are sequentially formed on a substrate. Then, a patterned photoresist layer having at least one photoresist stripe is formed to partially cover the hard mask layer. Thereafter, an ion-implant process is performed on hard mask layer with the patterned photoresist layer as a mask to form doped regions therein. Afterwards, at least one acid-crosslinked polymer spacer is formed on the sidewalls of at least one photoresist stripe to surpass a resolution limit of the patterned photoresist layer. Specifically, the patterned photoresist layer and the at least one acid-crosslinked polymer spacer are configured to define a plurality of first openings in the hard mask layer, and the doped regions of the hard mask layer is configured to further define a plurality of second openings therein.

### BACKGROUND OF THE INVENTION

1. Field of the Invention

The instant disclosure relates to a patterning technology; in particular, to a method for fabricating a patterned structure of semiconductor device.

2. Description of Related Art

As the degree of integration of a memory device is getting higher, the dimension of the same is getting smaller, and the channel length becomes shorter to increase the device operation speed

Due to the great demand of higher and higher integration, integrated circuit devices have to be fabricated with a smaller and smaller dimension. The photolithography process is a very crucial step that affects the dimension and performance of a semiconductor device. For example, in a metal-oxide semiconductor (MOS) device, the pattern of various thin films and the dopant regions are all determined by this photolithography step. Currently, device integration has reached a linewidth of 0.06 micron. The development of the photolithography process thus determines whether the linewidth can be approached. As a result, methods such as optical proximity correction (OPC) and phase shift mask (PSM) have been proposed and used.

However, the resolution of pattern transfer is increased and the critical dimension of the line width is reduced. However, limitation exists for improving lithography by only optical improvement. For example, look at optical lithography that is generally used by the industry in the past, due to the characteristics of optical physics, it cannot reduce the line width nor increase the resolution of pattern transfer as the line width reaches below 65 nm to 45 nm. The present invention aims to remedy the limitation.

### SUMMARY OF THE INVENTION

Accordingly, the prevent invention is to provide a method for fabricating a patterned structure of semiconductor device that can overcome the limitations of photolithography to match the miniaturization of semiconductor components.

To achieve these and other advantages and in accordance with the purpose of the present invention, as embodied and broadly described herein, the method for fabricating a patterned structure of semiconductor device comprises the following steps. The first step is sequentially forming a target layer and a hard mask layer on a substrate. The next step is forming a patterned photoresist layer on the hard mask layer to partially expose the surface of the hard mask layer, wherein the patterned photoresist layer has at least one photoresist stripe. The next step is ion-implanting the exposed surface of the hard mask layer to form a plurality of doped regions within the hard mask layer. The next step is forming at least one acid-crosslinked polymer spacer on the sidewalls of the at least one photoresist stripe, wherein the acid-crosslinked polymer spacer is formed to have a thickness to surpass a resolution limit of the patterned photoresist layer. The next step is selectively removing the hard mask layer to form a plurality of first openings. The next step is removing the patterned photoresist layer and the at least one acid-crosslinked polymer spacer. The next step is removing the un-doped regions of the hard mask layer to form a plurality of second openings. The last step is selectively removing the target layer through the first and second openings to become a transcribing pattern.

The prevent invention also provide a patterned structure of semiconductor device fabricated by the method, as embodied and broadly described herein, that comprises a substrate, a target layer, a hard mask layer, and a patterned photoresist layer, and a plurality of acid-crosslinked polymer spacers. The target layer, the hard mask layer, and the patterned photoresist layer are sequentially formed on the substrate. The patterned photoresist layer has a least one photoresist stripe, and the hard mask layer has a plurality of doped regions formed therein via a masked implantation process with the patterned photoresist layer as a mask. At least one acid-crosslinked polymer spacer is formed to connect the sidewalls of the at least one photoresist stripe to surpass a resolution limit of the patterned photoresist layer. Specifically, the patterned photoresist layer and the at least one acid-crosslinked polymer spacer are configured to define a plurality of first openings in the hard mask layer, and the doped regions of the hard mask layer is configured to further define a plurality of second openings therein.

In the present invention, the at least one acid-crosslinked polymer spacer is formed to act as a self-aligned mask to define the first openings via an anisotropic etching process. Moreover, the hard mask layer with doped regions and un-doped regions is formed to define the second openings via an isotropic etching process. Hence, the instant method can overcome the limitations of photolithography to improve the resolution of the pattern transfer.

In order to further appreciate the characteristics and technical contents of the instant disclosure, references are hereunder made to the detailed descriptions and appended drawings in connection with the instant disclosure. However, the appended drawings are merely shown for exemplary purposes, rather than being used to restrict the scope of the instant disclosure.

### BRIEF DESCRIPTION OF THE DRAWINGS

FIG. 1 shows a process flow diagram of a method for fabricating a patterned structure of semiconductor device according to an embodiment of the present invention;

FIGS. 2-8 are cross-sectional diagrams illustrating the processing steps of the method for fabricating a patterned structure of semiconductor device.

### DETAILED DESCRIPTION OF THE PREFERRED EMBODIMENTS

The aforementioned illustrations and following detailed descriptions are exemplary for the purpose of further explaining the scope of the instant disclosure. Other objectives and advantages related to the instant disclosure will be illustrated in the subsequent descriptions and appended drawings.

The present invention discloses a patterning method, and more specifically to a method for fabricating a patterned structure of semiconductor device by a ion-implanted hard mask and at least one acid-crosslinked polymer spacer to define a transcribing pattern on a target layer.

Reference will now be made in detail to the present preferred embodiment of the invention, examples of which are illustrated in the accompanying drawings. Wherever possible, the same reference numbers are used in the drawings and the description to refer to the same or like parts.

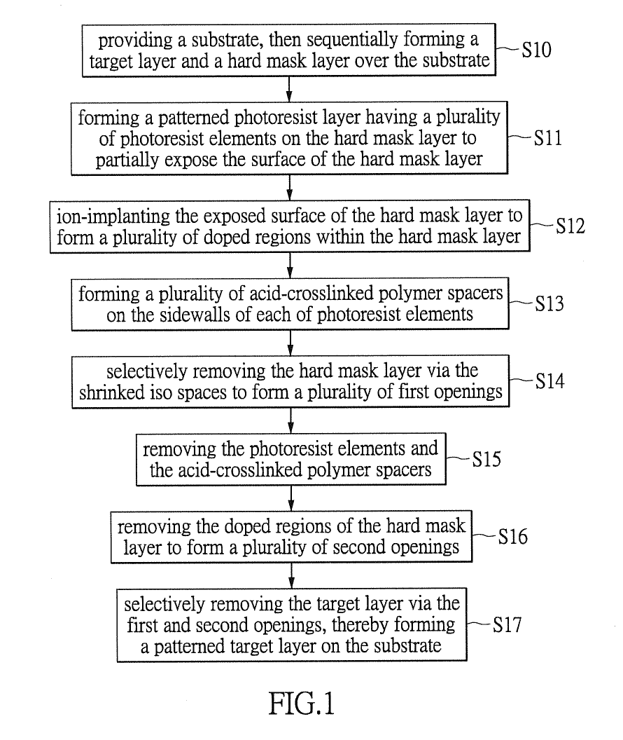

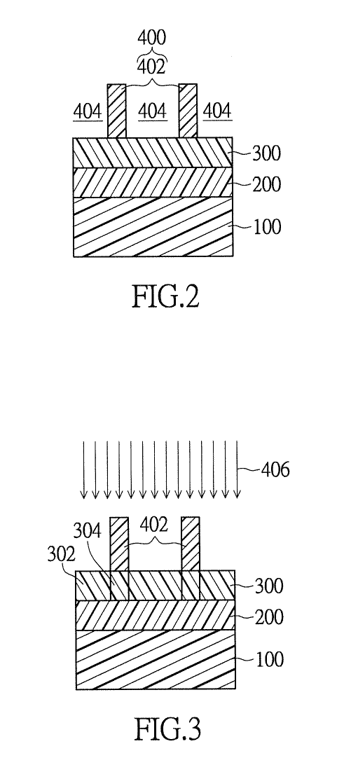

Please refer to FIG. 1 as well as FIGS. 2 to 8. FIG. 1 is a process diagram of a method for fabricating a patterned structure of semiconductor device according to a preferred embodiment of the instant disclosure. FIGS. 2 to 8 are schematic cross-sectional diagrams illustrating a series of steps carried out to fabricate a patterned structure of semiconductor device. Basically, the method of this invention has the following steps:

Step S10 is providing a substrate 100, then sequentially forming a target layer 200 and a hard mask layer 300 over the substrate 100. Referring to FIG. 2, the target layer 200 and the hard mask layer 300 are formed by chemical vapor deposition process, for example. In this embodiment, the substrate 100 may be semiconductor substrate, such as a silicon substrate or a combined substrate having a pad oxide layer (not shown) combined with a dielectric layer (not shown). Preferably, the thickness of the substrate 100 is about A₁ nm to A₂ nm. The target layer 200 includes polysilicon, amorphous silicon, or metal. Preferably, the thickness of the target layer 200 is about B₁ nm to B₂ nm. The hard mask layer 300 includes TEOS-SiO2, BPSG PSG, HSQ, FSG or USG. Preferably, the thickness of the hard mask layer 300 is about C₁ nm to C₂ nm.

Step S11 is forming a patterned photoresist layer 400 having at least one photoresist stripe 402 on the hard mask layer 300 to partially expose the surface of the hard mask layer 300. Concretely speaking, said step S11 comprises, but not limited to, the following steps. First, a photoresist material is spin-coated on the hard mask layer 300. Then, the photoresist material is exposed and developed through a photo mask to form the patterned photoresist layer 400, wherein a gap 404 between the two adjacent photoresist stripes 402 may be kept to be several hundred micrometers.

Step S12 is ion-implanting the exposed surface of the hard mask layer 300 to form a plurality of doped regions 302 within the hard mask layer 300. Referring to FIG. 3, a masked implantation process is performed to implant trivalent ions or pentavalent ions on the hard mask layer 300 with the patterned photoresist layer 400 as a mask. In this way, ions are forced in from the direction indicated by arrows of ion implanting direction 406, which is perpendicular to the surface of hard mask layer 300 to form doped regions 302 within the hard mask layer 300. Accordingly, a plurality of un-doped regions 304 are defined between the doped regions 302, and a high etching selection ratio is performed between the doped regions 302 and un-doped regions 304 of the hard mask layer 300.

In this embodiment, the trivalent ion is boron, and the pentavalent ion is boron difluoride (BF₂). Further, the masked implantation process is performed with energy between 5 keV and 20 keV. Moreover, the masked implantation process is performed with ion concentration between 10.sup.14 ions/cm.sup.2 to 10.sup.15 ions/cm.sup.2.

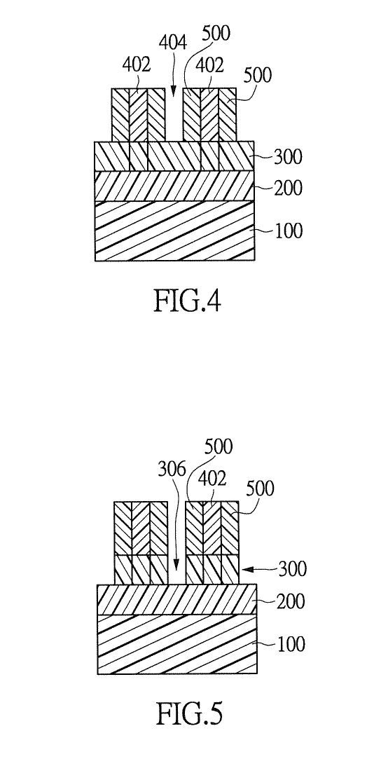

Step S13 is forming at least one acid-crosslinked polymer spacers 500 on the sidewalls of the at least one photoresist stripe 402. Concretely speaking, with reference to FIG. 4, said step S13 comprises, but not limited to, the following steps. First, a resolution-enhancement-lithography-assist-by-chemical-shrink (RELACS) material is provided over the sidewalls of the at least one photoresist stripe 402. The RELACS material refers to materials that are suitable for use in a RELACS process. Then, a baking process is performed to heat the RELACS material at a temperature range between 80 to 140.degree. C. for about D₁ to D₂ seconds.

Accordingly, the RELACS material can be baked to cause a cross-linking reaction between the at least one photoresist stripe 402. In this way, the acidic ions diffuse from the surfaces of the at least one photoresist stripe 402 into the RELACS material to polymerize the RELACS material to form the at least one acid-crosslinked polymer spacer 500 which has a thickness that help shrink the gap 404 between the two adjacent photoresist stripes 402 to surpass a resolution limit of the patterned photoresist layer 400. It is notable that the resolution limit is determined by the critical dimension (CD) of the gap 404.

Step S14 is selectively removing the hard mask layer 300 to form a plurality of first openings 306. Referring to FIG. 5, a dry-etching process is performed to the hard mask layer 300, so as to define the first openings 306 therein. During the step of defining the first openings 306, the patterned photoresist layer 400 and the at least one acid-crosslinked polymer spacer 500 act as masks to selectively remove a portion of the hard mask layer 300.

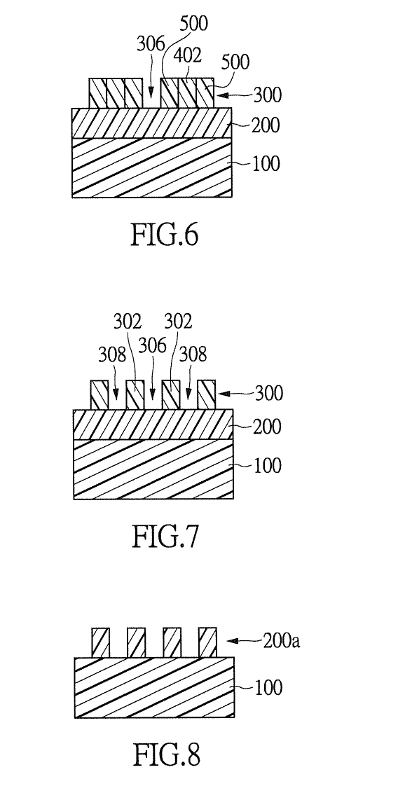

Step S15 is removing the patterned photoresist layer 400 and the at least one acid-crosslinked polymer spacer 500. Referring to FIG. 6, a dry-etching process or a CMP (Chemical Mechanical Polishing) process is performed to remove the patterned photoresist layer 400 and the at least one acid-crosslinked polymer spacer 500 together to expose the top of the un-doped regions 304 of the hard mask layer 300.

Step S16 is removing the doped regions 302 of the hard mask layer 300 to form a plurality of second openings 308. Referring to FIG. 7, a wet-etching process is performed to remove the un-doped regions 304 of the hard mask layer 300 according to the etching selection ratio between the doped regions 302 and un-doped regions 304. Thus, the un-doped regions 304 of the hard mask layer 300 are removed to form the second openings 308. That is, a transcribing pattern is defined on the hard mask layer 300. In this embodiment, the un-doped regions 304 are removed via at least hydrofluoric acid and nitric acid etching solution, for example.

Step S17 is selectively removing the target layer 200 through the first and second openings 306, 308, thereby forming a patterned target layer on the substrate 100. Referring to FIG. 8, a dry-etching process is performed to the target layer 200 to transfer the transcribing pattern of the hard mask layer 300 onto the target layer 200. In this embodiment, a portion of the target layer 200 is removed via at least the gas mixture of CHF₃ and O₂, or the gas mixture of CHF₂, CHF₃, and N₂.

Through the abovementioned steps, a patterned structure of semiconductor device can be fabricated. Referring to FIGS. 4 and 7, the patterned structure of semiconductor device comprises a substrate 100, a target layer 200, a hard mask layer 300, and a patterned photoresist layer 400, and at least one acid-crosslinked polymer spacer 500.

The target layer 200, the hard mask layer 300, and the patterned photoresist layer 400 are sequentially formed on the substrate 100. The patterned photoresist layer 400 has at least one photoresist strip 402, and the hard mask layer 300 has a plurality of doped regions 302 formed therein via a masked implantation process with the patterned photoresist layer 400 as a mask. The at least one acid-crosslinked polymer spacer 500 is connected to the sidewalls of the at least one photoresist strip 402. Specifically, the patterned photoresist layer 400 and the at least one acid-crosslinked polymer spacer 500 are configured to define a plurality of first openings 306 in the hard mask layer 300, and the un-doped regions 304 of the hard mask layer 300 is configured to further define a plurality of second openings 308 therein.

Based on above, the instant method for fabricating a patterned structure of semiconductor device, in comparison with the traditional one, has the following advantages: Firstly, for the instant method, the at least one acid-crosslinked polymer spacer is formed to act as self-aligned masks to define the first openings via an anisotropic etching process. Moreover, the hard mask layer with doped regions and un-doped regions is formed to define the second openings via an isotropic etching process. Hence, the instant method can overcome the limitations of photolithography to match the miniaturization of semiconductor components.

Secondly, the at least one acid-crosslinked polymer spacer is formed by a cross-linking reaction between the RELACS material and the at least one photoresist stripe. In this way, the thickness of the at least one acid-crosslinked polymer spacer can be controlled by the baking temperature, thereby shrinking the gap between the two adjacent photoresist stripes.

Further, the process window/allowance of the instant method can be improved. Therefore, the smaller opening can be formed by the existing manufacturing equipment to reduce cost.

The descriptions illustrated supra set forth simply the preferred embodiments of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims.

What is claimed is:

1. A method for fabricating a patterned structure of semiconductor device, comprising:
sequentially forming a target layer and a hard mask layer on a substrate;
forming a patterned photoresist layer on the hard mask layer to partially expose the surface of the hard mask layer, wherein the patterned photoresist layer has at least one photoresist stripe;
ion-implanting the exposed surface of the hard mask layer to form a plurality of doped regions within the hard mask layer;
forming at least one acid-crosslinked polymer spacer on the sidewalls of the photoresist stripe, wherein the acid-crosslinked polymer spacer is formed to have a thickness to surpass a resolution limit of the patterned photoresist layer;
selectively removing the hard mask layer to form a plurality of first openings;
removing the patterned photoresist layer and the at least one acid-crosslinked polymer spacer;
removing the un-doped regions of the hard mask layer to form a plurality of second openings; and
selectively removing the target layer through the first and second openings to become a transcribing pattern.

2. The method for fabricating a patterned structure of semiconductor device according to claim 1, wherein: said step of ion-implanting the exposed surface of the hard mask layer to form a plurality of doped regions within the hard mask layer further comprising a step of executing a masked implantation process to implant trivalent ions or pentavalent ions on the hard mask layer with the patterned photoresist layer as a mask.

3. The method for fabricating a patterned structure of semiconductor device according to claim 2, wherein the masked implantation process is performed with energy between 5 keV and 20 keV.

4. The method for fabricating a patterned structure of semiconductor device according to claim 2, wherein the masked implantation process is performed with ion concentration between 10.sup.14 ions/cm.sup.2 to 10.sup.15 ions/cm.sup.2.

5. The method for fabricating a patterned structure of semiconductor device according to claim 2, wherein the trivalent ion is boron, the pentavalent ion is boron difluoride (BF2).

6. The method for fabricating a patterned structure of semiconductor device according to claim 1, wherein the method of forming a plurality of acid-crosslinked polymer spacers on the sidewalls of the photoresist stripe comprises:
applying a RELACS material over the patterned photoresist layer; and
baking the RELACS material to form the acid-crosslinked polymer spacer.

7. The method for fabricating a patterned structure of semiconductor device according to claim 6, wherein the RELACS material is heated at a temperature range between 80 to 140.degree. C. in the step of baking the RELACS material to form the acid-crosslinked polymer spacer to control its thickness.

8. The method for fabricating a patterned structure of semiconductor device according to claim 1, wherein the un-doped regions of the hard mask layer are removed via a wet-etching process, and at least hydrofluoric acid and nitric acid etching solution in the step of removing the un-doped regions of the hard mask layer to form a plurality of second openings.

9. The method for fabricating a patterned structure of semiconductor device according to claim 1, wherein a portion of the target layer is removed via a dry-etching process, and at least the gas mixture of CHF₃ and O₂ in the step of selectively removing the target layer through the first and second openings to form a patterned target layer.

10. The method for fabricating a patterned structure of semiconductor device according to claim 1, wherein a portion of the target layer is removed via a dry-etching process, and at least the gas mixture of CHF₂, CHF₃, and N₂ in the step of selectively removing the target layer through the first and second openings to form a patterned target layer.

11. A patterned structure of semiconductor device, comprising:
a substrate;
a target layer, a hard mask layer, and a patterned photoresist layer sequentially formed on the substrate, wherein the patterned photoresist layer has a least one photoresist stripe, and the hard mask layer has a plurality of doped regions formed therein via a masked implantation process with the patterned photoresist layer as a mask; and
at least one acid-crosslinked polymer spacer formed to connect the sidewalls of the at least one photoresist stripe to surpass a resolution limit of the patterned photoresist layer;
wherein the patterned photoresist layer and the at least one acid-crosslinked polymer spacer are configured to define a plurality of first openings in the hard mask layer;
wherein the un-doped regions of the hard mask layer is configured to further define a plurality of second openings therein.

12. The patterned structure of semiconductor device according to claim 11, wherein the material of the target layer is polysilicon.

13. The patterned structure of semiconductor device according to claim 11, wherein the material of the target layer is amorphous silicon.

14. The patterned structure of semiconductor device according to claim 11, wherein the thickness of the target layer is in a range between B₁ nm to nm.

15. The patterned structure of semiconductor device according to claim 11, wherein the material of the hard mask layer is selected from the group consisting of TEOS-SiO₂, BPSG, PSG, HSQ, FSG and USG.

16. The patterned structure of semiconductor device according to claim 11, wherein the thickness of the hard mask layer is in a range between C₁ nm to C₂ nm.

17. The patterned structure of semiconductor device according to claim 11, wherein each of the doped regions of the hard mask layer is a trivalent ion-doped region.

18. The patterned structure of semiconductor device according to claim 17, wherein the trivalent ion is boron.

19. The patterned structure of semiconductor device according to claim 11, wherein each of the doped regions of the hard mask layer is a pentavalent ion-doped region.

20. The patterned structure of semiconductor device according to claim 19, wherein the pentavalent ion is boron difluoride (BF₂).
